(19) United States
(12) Patent Application Publication
(10) Pub. No.: US 2005/0142784 A1
(43) Pub. Date: Jun. 30, 2005

(54) Methods of fabricating semiconductor devices

(76) Inventor: Dae Kyeun Kim, Yongin (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/027,363

(22) Filed: Dec. 29, 2004

(30) Foreign Application Priority Data
Dec. 30, 2003 (KR) 2003-0100948

(51) Int. Cl. H01L 21/3205; H01L 21/336; H01L 21/4763

(52) U.S. Cl. 438/303; 438/305

(57) ABSTRACT

Methods of fabricating semiconductor devices are disclosed wherein void generation in an insulating interlayer between a pair of gate electrodes is prevented. An illustrated method includes: forming a gate on a semiconductor substrate, forming lightly doped regions in the substrate, forming spacers on sidewalls of the gate with liners disposed between respective ones of the spacers and the sidewalls, forming heavily doped regions which are partially overlapped with the lightly doped regions, removing the spacers, forming an insulating layer over the semiconductor substrate, and forming an insulating interlayer on the insulating layer.

### FIELD OF THE DISCLOSURE

The present disclosure relates generally to semiconductor fabrication and, more particularly, to methods of fabricating semiconductor devices wherein gap-filling can be performed without generating voids when forming an insulating interlayer on an area between adjacent gate electrodes.

### BACKGROUND

Generally, transistors are continually being microscopically reduced in size in accordance with a highly increasing degree of integration in semiconductor devices. Transistors require a high operational speed to keep up with the highly increasing degree of integration in semiconductor devices. However, sheet resistance and contact resistance keep rising which creates difficulties in sustaining desired transistor characteristics. Nevertheless, the demand for continuing to highly increase the degree of integration and the corresponding operational speed of semiconductor devices will continue to rise.

To meet such a demand, silicidation has been developed. In silicidation, the silicon of a source/drain of a silicon and/or polysilicon gate electrode react with a high melting point metal having a low specific resistance (e.g., Ti, Co, Ni and/or the like) to produce a silicide layer that can considerably lower the gate electrode resistance and the contact resistance.

When silicidation was initially developed, a silicide layer was separately provided for each of the gate electrode and the source/drain. Recently, techniques have been developed for simultaneously forming the silicide layer on the gate electrode and the source/drain in a single salicidation process. A salicide (e.g., a self-aligned silicide) layer is formed by forming a silicide layer and then selectively removing the high melting point metal which fails to react with silicon.

Transistor fabrication has begun adopting salicidation in place of a conventional salicide forming process using chemical vapor deposition (CVD). Specifically, Ti-silicidation has an excellent resistance characteristic and is popular in transistor fabrication.

FIG. 1 is a cross-sectional diagram illustrating a prior art semiconductor device in which a void is formed in an insulating interlayer. Referring to FIG. 1, a gate electrode 13 having a gate oxide layer 11 underneath is formed on an active area of a semiconductor substrate 10.

A pair of N− type LDD (lightly doped drain) regions are formed in the semiconductor substrate 10 with the gate electrode 13 in-between.

Spacers 17 are formed on sidewalls of the gate electrode 13. An oxide layer 15 is inserted between the spacers 17 and the sidewalls of the gate electrode 13.

A pair of N+ type source/drain regions is then formed in the semiconductor substrate 10 with the gate electrode 13 and the spacers 17 in-between.

Silicide layers 21 and 23 are formed on the gate electrode 13 and the N+ type source/drain regions.

A nitride layer 25 is formed over the semiconductor substrate 10 including over the silicide layers 21 and 23 and the spacers 17.

An insulating interlayer 27 is then formed on the nitride layer 25. The insulating interlayer 27 is then planarized.

However, in the prior art semiconductor device, a gap between the opposed spacers 17 of two adjacent gate electrodes 13 is narrow due to the highly increasing degree of integration. Consequently, the gap filling capability of the insulating interlayer 27 between the confronting spacers 17 is lowered.

In depositing the insulating interlayer 27 on the semiconductor substrate 10, the lowered gap filing capability causes a void 28 to be formed in the insulating interlayer 27 between the opposed spacers 17. The void 28 renders the insulating interlayer 27 vulnerable to annealing cracks and can cause an unwanted electrical connection (i.e., a bridge) between adjacent contacts, thereby lowering the reliability and the yield of the semiconductor device.

To overcome this problem, the impurity (B, P) density or the deposition temperature of a BPSG (borophospho silicate glass) layer used as the insulating interlayer 27 may be varied to enhance the gap filling capability of the BPSG layer. However, this method causes variations in the electrical characteristics due to the high impurity density or the high temperature deposition, thereby rendering the technique substantially unusable in semiconductor device fabrication.

### BRIEF DESCRIPTION OF THE DRAWINGS

FIG. 1 is a cross-sectional diagram illustrating a prior art semiconductor device, in which a void is formed in an insulating interlayer.

FIGS. 2A to 2F are cross-sectional diagrams illustrating an example method of fabricating a semiconductor device performed in accordance with the teachings of the present invention.

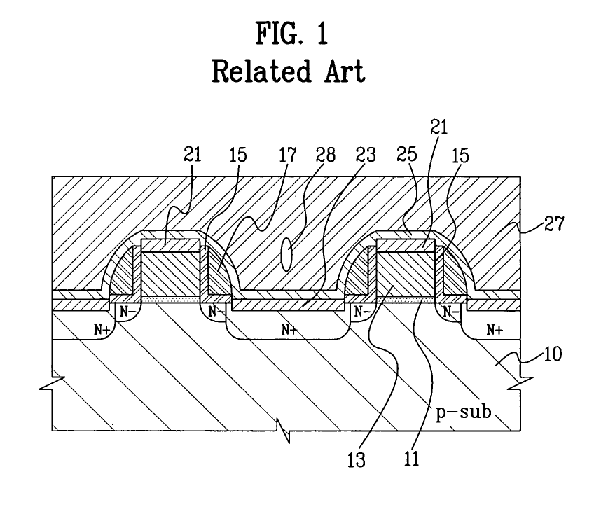

Wherever possible, the same reference numbers will be used throughout the drawings to refer to the same or like parts.

### DETAILED DESCRIPTION

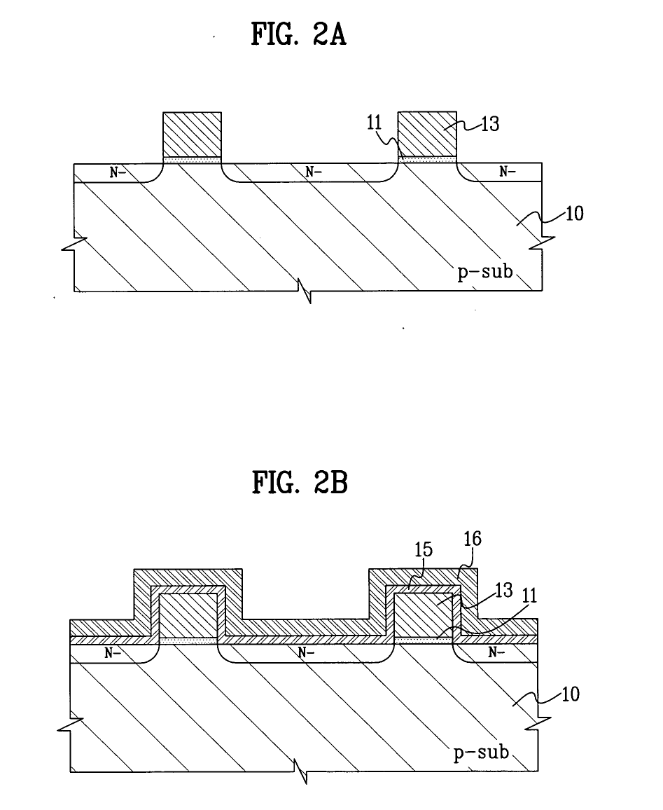

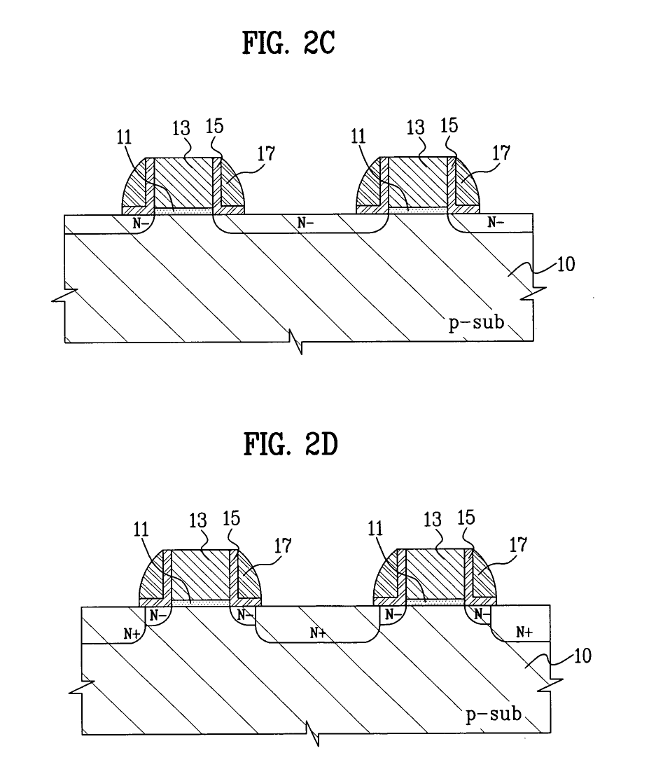

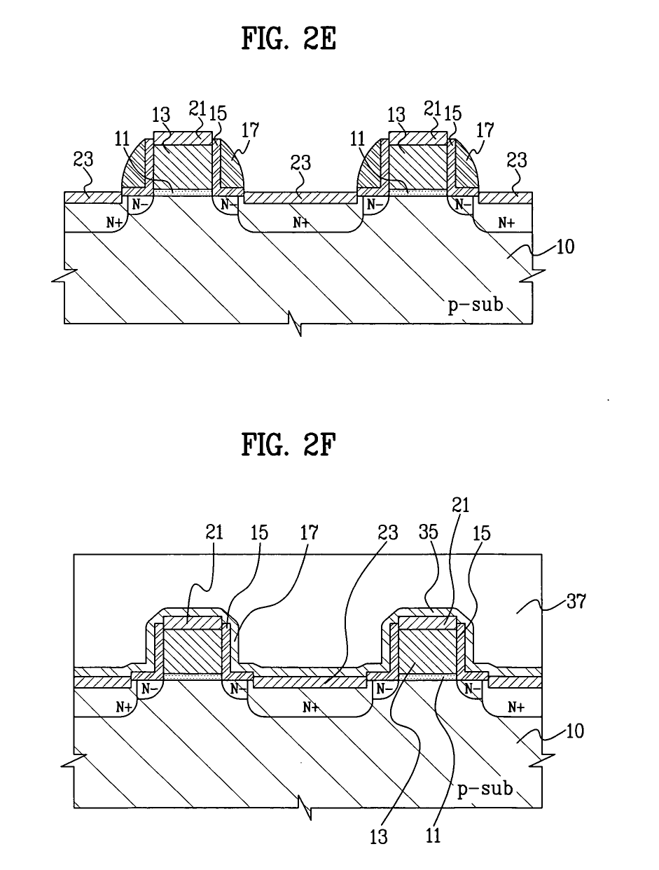

FIGS. 2A to 2F are cross-sectional diagrams illustrating an example method of fabricating a semiconductor device performed in accordance with the teachings of the present invention. A device isolation layer (not shown in the drawings) is formed on a field area of a semiconductor substrate 10 to define an active area by shallow trench isolation (STI) or local oxidation of silicon (LOCOS). Referring to FIG. 2A, the illustrated example semiconductor substrate 10 is a P type, single crystalline silicon substrate.

A gate oxide layer 11 is formed on the active area of the semiconductor substrate 10. A conductive layer for a gate electrode 13 is deposited on the gate oxide layer 11. In the illustrated example, a polysilicon layer is used as the conductive layer. The polysilicon layer and the gate oxide layer 11 are selectively removed by photolithography to simultaneously form a gate electrode 13 and a gate oxide layer 11 on a gate electrode forming area in the active area of the semiconductor substrate 10.

Subsequently, LDD ion implantation is carried out on the substrate using the gate electrode 13 as a mask to form N− LDD regions in the active area of the semiconductor substrate 10.

Referring to FIG. 2B, an oxide liner 15 is formed over the semiconductor substrate 10 including over the gate electrode 13 and the N− LDD regions by CVD. In the illustrated example, the oxide liner 15 is about 150˜300 Å thick. An insulating layer, (e.g., a nitride layer 16), is deposited on the oxide liner 15 for subsequently forming the spacers 17 shown in FIG. 2C.

Referring to FIG. 2C, the nitride layer 16 and the oxide liner 15 are etched back until a topside of the gate electrode 13 and surfaces of the N− LDD regions are exposed to form spacers 17 on opposite sidewalls of the gate electrodes 13. Portions of the oxide liner 15 remain between the nitride layer 16/spacers 17 and the sidewalls of the gate electrodes 13.

Referring to FIG. 2D, LDD ion implantation is performed on the substrate 10 using the gate electrodes 13 and the spacers 17 as an ion implantation mask to form N+ source/drain regions. The N+ source/drain regions are partially overlapped with the N− LDD regions in the active area of the substrate 10.

Referring to FIG. 2E, a silicide forming metal layer is deposited by sputtering over the substrate 10 including over the gate electrode 13, over the N+ source/drain regions, and over the spacers 17. In the illustrated example, a barrier metal layer such as a Ti/TiN layer is deposited to a prescribed thickness.

In the illustrated example, the Ti/TiN layer is thermally treated for salicidation at about 800˜1,050° C. for a time period of about 10˜30 seconds by rapid thermal processing. As a result, salicide layers 21 and 23 are formed on the gate electrodes 13 and the source/drain regions, respectively.

The portion(s) of the Ti/TiN layer which fail to react in the salicidation process are removed by wet etching to expose the spacers 17.

Referring to FIG. 2F, the spacers 17 are removed by dry etching, wet etching, or a combination of dry and wet etching to expose the oxide liner 15.

Optionally, thermal oxidation can be performed prior to removing the spacers 17 to compensate for etching damage of the oxide liner 15. Optionally, an oxide layer cleaning process can be performed prior to removing the spacers 17 to completely remove native oxide on the spacers 17.

Subsequently, a nitride layer 35 is deposited over the semiconductor substrate 10 including over the silicide layers 21 and 23 and the oxide liner 15. In the illustrated example, the nitride layer 35 is about 300˜400 Å thick.

An insulating interlayer 37 is then deposited thickly enough to fill a gap between the adjacent gate electrodes 13. In the illustrated example, a BPSG layer may be thickly formed as the insulating interlayer 37.

The insulating interlayer 37 is then planarized by, for example, chemical mechanical polishing (CMP).

The nitride layer 35 functions as a diffusion barrier layer to prevent impurities of the insulating interlayer 37 from diffusing into the gate electrode 13 and also functions as an etch stop layer when forming a contact hole through the insulating interlayer 37.

In the illustrated example, the gap between the opposed oxide liners 15 of the adjacent gate electrodes 13 is wider than the gaps between the prior art spacers. Consequently, void generation can be prevented from occurring when depositing the insulating interlayer 37 between the adjacent gate electrodes 13.

After planarizing the insulating interlayer 37, conventional contact hole forming process(es), conventional line forming process(es), and the like are performed to complete the semiconductor.

Persons of ordinary skill in the art will appreciate that the above described method is also applicable in the same manner even if the silicide forming process is skipped.

From the foregoing, persons of ordinary skill in the art will appreciate that the above described method prevents void generation in an insulating interlayer between a pair of gate electrodes. As a result, the insulating interlayer is prevented from cracking, thereby avoiding unwanted electrical connection between adjacent contacts. Consequently, device reliability is enhanced, and the yield of the semiconductor device fabrication process is increased.

A disclosed example method of fabricating a semiconductor device comprises: forming a gate on an active area of a semiconductor substrate, forming a pair of lightly doped regions in the active area, forming spacers on sidewalls of the gate with a liner in-between the spacers and the sidewalls, forming a pair of heavily doped regions in the active area, the heavily doped regions partially overlapping the lightly doped regions, removing the spacers, forming an insulating layer over the semiconductor substrate including over the heavily doped regions and the liner, and forming an insulating interlayer on the insulating layer.

Preferably, the method further includes forming a silicide layer on the gate electrodes and on the heavily doped regions prior to removing the spacers.

Preferably, the spacers are removed by dry etching, wet etching, and/or dry and wet etching.

Preferably, the spacers are formed from a nitride layer.

Preferably, the liner is formed from an oxide layer.

Preferably, removing the spacers includes: oxidizing the liner, removing native oxide from the spacers, and removing the spacers to expose the liner.

It is noted that this patent claims priority from Korean Patent Application Serial Number P2003-0100948, which was filed on Dec. 30, 2003, and is hereby incorporated by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. A method of fabricating a semiconductor device comprising:
forming a gate on a semiconductor substrate;
forming lightly doped regions in the substrate;
forming spacers on sidewalls of the gate with liners disposed between respective ones of the spacers and the sidewalls;
forming heavily doped regions in the substrate, the heavily doped regions partially overlapping the lightly doped regions, respectively;
removing the spacers;
forming an insulating layer; and
forming an insulating interlayer on the insulating layer.

2. A method as defined in claim 1, further comprising forming a silicide layer on the gate and the heavily doped regions prior to removing the spacers.

3. A method as defined in claim 1, wherein removing the spacers comprises dry etching, wet etching, or a combination of dry etching and wet etching.

4. A method as defined in claim 1, wherein the spacers are formed from a nitride layer.

5. A method as defined in claim 1, wherein the liners are formed from an oxide layer.

6. A method as defined in claim 1, wherein removing the spacers comprises:
oxidizing the liners;
removing native oxide from the spacers; and
removing the spacers to expose the liners.
